(19) United States
(12) Patent Application Publication
(10) Pub. No.: US 2026/0114011 A1
(43) Pub. Date: Apr. 23, 2026

(54) SEMICONDUCTOR DEVICE AND METHOD FOR MANUFACTURING THE SAME

(71) Applicant: SAMSUNG ELECTRONICS CO., LTD., Suwon-si (KR)

(72) Inventors: GYEONG-SEON PARK, Suwon-si (KR); JONGWON PARK, Suwon-si (KR); JONGUK SEO, Suwon-si (KR); JIHOON YUN, Suwon-si (KR); JeongPyo Hong, Suwon-si (KR); YOUNGCHEOL KIM, Suwon-si (KR); JONGSEOB KIM, Suwon-si (KR)

(73) Assignee: SAMSUNG ELECTRONICS CO., LTD., Suwon-si (KR)

(21) Appl. No.: 19/209,446

(22) Filed: May 15, 2025

(30) Foreign Application Priority Data
Oct. 21, 2024 (KR) 10-2024-0143829

(51) Int. Cl. H10D 64/23; H01L 21/304; H01L 23/00; H10D 30/63; H10D 62/13; H10D 62/832

(52) U.S. Cl. CPC H10D 64/2527; H10D 30/63; H10D 62/151; H10D 62/8325; H10P 52/00; H10W 42/121

(57) ABSTRACT

A method for manufacturing a semiconductor device is provided. The method includes: forming a first conductivity type semiconductor layer on a first surface of a substrate containing SiC; forming a doping layer by implanting ions into the first conductivity type semiconductor layer; forming a gate insulation layer on the first conductivity type semiconductor layer; forming a gate electrode on the gate insulation layer; forming a source electrode connected to the doping layer; reducing a thickness of the substrate by performing a thinning process on a second surface opposite to the first surface of the substrate; and forming a groove in the substrate on the second surface.

### CROSS-REFERENCE TO RELATED APPLICATION

This application claims priority to Korean Patent Application No. 10-2024-0143829, filed on Oct. 21, 2024, in the Korean Intellectual Property Office, the disclosure of which is incorporated by reference herein in its entirety.

### BACKGROUND

### 1. Field

The present disclosure relates to a semiconductor device and a method for manufacturing the same.

### 2. Description of Related Art

Semiconductor devices are closely related to daily life. An electric power semiconductor device is a semiconductor device used to handle high voltage or high current, and performs functions such as electric power conversion and control in large electric power systems or high power electronic devices. The electric power semiconductor device may be used in various fields, including transportation, such as electric vehicles, railways, and electric trams; renewable energy systems, such as solar power generation and wind power generation; and mobile devices. The electric power semiconductor device has an ability to handle high electric power and durability, so it can handle large amounts of current and endure high voltages. For example, an electric power semiconductor device may handle voltages ranging from hundreds to thousands of volts, and currents ranging from tens to thousands of amperes. The electric power semiconductor device may minimize power loss to improve the efficiency of electrical energy. Additionally, electric power semiconductor device may be operated stably even in a high temperature environment.

These electric power semiconductor devices may be classified according to material, and, for example, may contain SiC electric power semiconductor device and GaN electric power semiconductor device. By manufacturing an electric power semiconductor device using SiC or GaN instead of silicon wafers (Si wafers), the drawbacks of silicon which has unstable characteristics at high temperatures may be compensated. These electric power semiconductor devices may be classified according to material, and, for example, may contain SiC electric power semiconductor device and GaN electric power semiconductor device. The GaN electric power semiconductor device requires high costs, but it is efficient in terms of speed and suitable for high-speed charging of mobile devices.

### SUMMARY

One or more example embodiments provide a semiconductor device with improved reliability.

According to an aspect of an example embodiment, a method for manufacturing a semiconductor device, includes: forming a first conductivity type semiconductor layer on a first surface of a substrate containing SiC; forming a doping layer by implanting ions into the first conductivity type semiconductor layer; forming a gate insulation layer on the first conductivity type semiconductor layer; forming a gate electrode on the gate insulation layer; forming a source electrode connected to the doping layer; reducing a thickness of the substrate by performing a thinning process on a second surface opposite to the first surface of the substrate; and forming a groove in the substrate on the second surface.

According to another aspect of an example embodiment, a semiconductor device includes: a substrate including a first surface and a second surface facing each other; a first conductivity type semiconductor layer provided on the first surface of the substrate; a doping layer provided in the first conductivity type semiconductor layer; a gate electrode provided on the first conductivity type semiconductor layer; a gate insulation layer provided between the first conductivity type semiconductor layer and the gate electrode; a source electrode connected to the doping layer; and a drain electrode provided on the second surface of the substrate. Grooves concavely recessed from the second surface toward the first surface are formed in the substrate. The drain electrode extends into the grooves.

According to another aspect of an example embodiment, a method of manufacturing a semiconductor device, includes: forming a first conductivity type semiconductor layer on a first surface of a substrate containing SiC; forming a doping layer by implanting ions into the first conductivity type semiconductor layer; forming a gate insulation layer on the first conductivity type semiconductor layer; forming a gate electrode on the gate insulation layer; forming a first interlayer insulation layer covering the gate electrode; forming a source electrode connected to the doping layer; forming a second interlayer insulation layer on the source electrode; reducing a thickness of the substrate by performing a thinning process on a second surface opposite to the first surface of the substrate; forming a drain electrode on the second surface of the substrate; and forming a groove in the substrate on the second surface.

A method for manufacturing a semiconductor device according to embodiments may form a plurality of grooves on a rear surface of the substrate if warpage occurs in the substrate during processes.

According to embodiments, it is possible to improve warpage occurring in a substrate during processes, and thus, the manufacturing process of a semiconductor device and the reliability of the semiconductor device manufactured thereby can be improved.

### BRIEF DESCRIPTION OF DRAWINGS

The above and other aspects and features will be more apparent from the following description of example embodiments with reference to the attached drawings, in which:

FIG. 1 is a top plan view illustrating a substrate of a semiconductor device according to an example embodiment.

FIG. 2 is a drawing to explain the direction of warpage.

FIG. 3 is a cross-sectional view of the semiconductor device of FIG. 1 taken along the line I1-I1′.

FIG. 4 is an enlarged cross-sectional view of the ‘A’ region of FIG. 3.

FIG. 5 to FIG. 20 are process cross-sectional views to explain the manufacturing process of a semiconductor device according to example embodiment.

FIG. 21 to FIG. 31 are drawings illustrating semiconductor devices according to various example embodiments.

### DETAILED DESCRIPTION

Hereinafter, with reference to accompanying drawings, various example embodiments will be described in detail. The present disclosure may be implemented in many different forms and is not limited to the specific examples described herein.

In order to clearly explain the present disclosure, parts that are not relevant to the description are omitted, and identical or similar components are assigned the same reference numerals throughout the specification.

In addition, the size and thickness of each component shown in the drawings may be shown arbitrarily for convenience of explanation, so the present disclosure is not necessarily limited to what is shown. In the drawings, the thickness of layers, films, panels, regions, etc., may be exaggerated for clarity. And in the drawings, for convenience of explanation, the thicknesses of some layers and regions may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element indicates being positioned on or below the reference element, and does not necessarily indicate being positioned “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

In addition, throughout the specification, when referring to “a plane view”, it indicates that the target portion is viewed from above, and when referring to “a cross-section view”, it indicates that a cross section of the target portion cut vertically is viewed from a side.

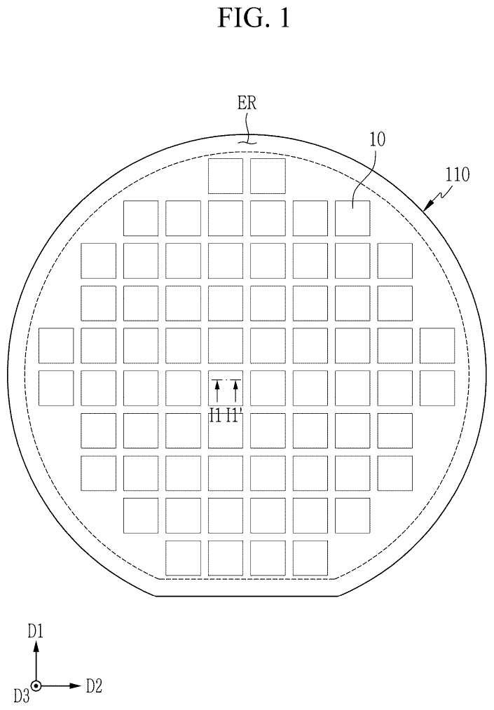

Hereinafter, a semiconductor device according to an example embodiment will be described referring to FIG. 1 to FIG. 4. FIG. 1 is a top plan view illustrating a substrate of a semiconductor device according to an example embodiment.

Referring to FIG. 1, the substrate 110 of the semiconductor device according to an example embodiment may be a semiconductor wafer having a substantially circular planar shape. In an example embodiment, the substrate 110 may include a flat region having a flat shape at one edge. The flat region may represent the direction of the crystal axis of substrate 110. In FIG. 1, only one flat region is shown formed at a side of substrate 110, but example embodiments are not limited thereto. For example, flat regions may be respectively formed at two different sides of substrate 110. For example, instead of a flat region, a notch may be formed at a side of the substrate 110 according to an example embodiment.

A plurality of layers included in the semiconductor device according to an example embodiment may be formed on the substrate 110. For example, a plurality of layers included in the semiconductor device according to an example embodiment may be formed by performing an epitaxial growth process, a doping process, and/or a thin film deposition process, which will be described later, on the upper surface and/or lower surface of substrate 110. The substrate 110 may include a plurality of unit chip regions 10. By forming a plurality of layers on a plurality of unit chip region 10 of a single substrate 110 and then performing a dicing process and the like a plurality of unit chip regions 10 may be separated to form a plurality of semiconductor devices. The substrate 110 may include an edge region (ER) positioned along a circumference of an edge of the substrate 110. The unit chip region 10 may not be positioned in the edge region (ER).

In an example embodiment, the semiconductor device may have a planar type metal-oxide-semiconductor field-effect transistor (MOSFET) structure. However, the structure of the semiconductor device is not limited thereto. For example, the semiconductor device may have a trench type MOSFET or a super junction type MOSFET structure. For example, the semiconductor device may have an insulated-gate bipolar transistor (IGBT) structure. For example, a semiconductor device may have a Schottky barrier diode structure too.

In an example embodiment, the substrate 110 may be a semiconductor substrate including SiC. For example, substrate 110 may be made of a 4H SiC substrate. In some cases, the substrate 110 may be made of a 3C SiC substrate, a 6H SiC substrate, etc. The substrate 110 may be doped by first conductivity type impurities. For example, the first conductivity type impurities may be n-type impurities. In this regard, the substrate 110 may be n-type doped. The substrate 110 may be n-type doped at a high concentration. The resistivity of the substrate 110 may be between about 0.005 Ω·cm and about 0.035 Ω·cm. The thickness of the substrate 110 may be from about 10 μm to about 700 μm. The material, doping type, doping concentration, resistivity, thickness, and the like of substrate 110 are not limited thereto and may be modified in various ways.

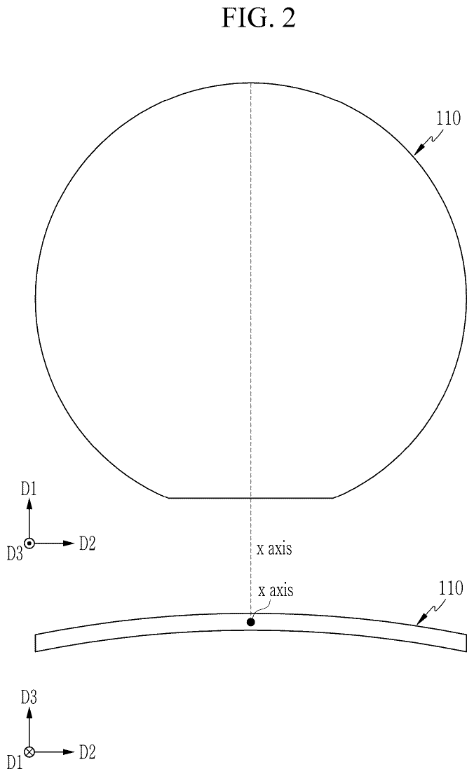

FIG. 2 is a drawing to explain the direction of warpage. The warpage may occur in the substrate 110 while forming the plurality of layers, which are described with reference to FIG. 1, on the substrate 110. Specifically, when manufacturing a semiconductor device according to an example embodiment, residual stress such as compressive stress or tensile stress may occur inside the substrate 110, and at this time, warpage may occur in the substrate 110 due to a difference in stresses at the front surface and the rear surface of the substrate 110. FIG. 2 illustrates that the substrate 110 is warped in a convex direction with respect to the front surface. However, example embodiments are not limited thereto and the warpage may be formed concavely with respect to the front surface of the substrate 110.

FIG. 2 illustrates a shape in which the substrate 110 is warped at both sides with respect to an arbitrary axis (x axis) extending along the first direction D1. In FIG. 2, the x axis is shown as passing through the center of the substrate 110 along the first direction D1 for convenience of description, but example embodiments are not limited thereto, the x axis may extend in various directions and may not pass through the center of the substrate 110. For example, the substrate 110 may have a shape that is warped at both sides with respect to an axis extending along a second direction D2, or may have a shape that is warped at both sides with respect to an axis extending along a diagonal between the first direction D1 and the second direction D2. For example, the substrate 110 may have a shape that is warped at both sides with respect to an axis passing between a center and an edge of substrate 110.

In the present disclosure, the substrate 110 being ‘warped along the x direction’ is used to indicate that the substrate 110 is bent at both sides with respect to the x axis extending in the x direction.

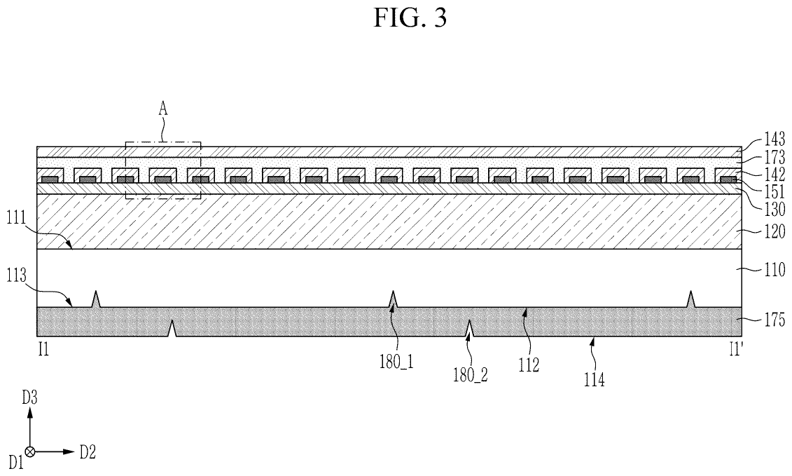

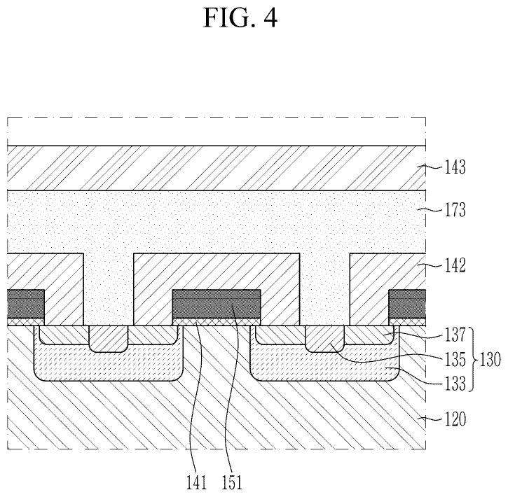

Hereinafter, the structure of a semiconductor device according to an example embodiment will be described with reference to FIG. 3 and FIG. 4. FIG. 3 is a cross-sectional view of the semiconductor device of FIG. 1 taken along the line I1-I1′. FIG. 4 is an enlarged cross-sectional view of the ‘A’ region of FIG. 3.

A semiconductor device according to an example embodiment may include a first conductivity type semiconductor layer 120 positioned on a first surface 111 of the substrate 110, a doping layer 130 positioned in the first conductivity type semiconductor layer 120, a gate electrode 151 positioned on the first conductivity type semiconductor layer 120, a source electrode 173 connected to the doping layer 130, and a drain electrode 175 positioned on a second surface 112 of the substrate 110. In the present disclosure, the first surface 111 of the substrate 110 may be referred to as an upper surface of the substrate 110, and the second surface 112 of the substrate 110 may be referred to as a lower surface of the substrate 110.

The first conductivity type semiconductor layer 120 may be positioned on the first surface, i.e., the upper surface, of the substrate 110. A lower surface of the first conductivity type semiconductor layer may be in contact with the upper surface of the substrate 110. However, example embodiments are not limited thereto, and another layer may be positioned between the substrate 110 and the first conductivity type semiconductor layer 120. The first conductivity type semiconductor layer 120 may be an epitaxial layer formed from the substrate 110 using an epitaxial growth method.

The first conductivity type semiconductor layer 120 may contain SiC. For example, the first conductivity type semiconductor layer 120 may contain 4H SiC. The first conductivity type semiconductor layer 120 may be n-type doped. The first conductivity type semiconductor layer 120 may be n-type doped at a low concentration. The doping concentration of the first conductivity type semiconductor layer 120 may be lower than the doping concentration of the substrate 110.

A doping layer 130 may be positioned in the first conductivity type semiconductor layer 120. The doping layer 130 may be formed, for example, by implanting ions into the first conductivity type semiconductor layer 120. In an example embodiment, the doping layer 130 may include a second conductivity type doping well region 133, a second conductivity type doping layer 135, and a first conductivity type doping layer 137.

The second conductivity type doping well region 133 may be positioned in the first conductivity type semiconductor layer 120. The second conductivity type doping well region 133 may be positioned on the first conductivity type semiconductor layer 120. The second conductivity type doping well region 133 may be in contact with a lower surface of the second conductivity type doping layer 135. The second conductivity type doping well region 133 may surround the lower surface and side surface of the first conductivity type doping layer 137. In an example embodiment, at least a portion of the upper surface of the second conductivity type doping well region 133 may overlap with at least a portion of the gate electrode 151 and at least a portion of the gate insulation layer 141, in the third direction D3. In an example embodiment, the third direction D3 may indicate a thickness direction of the substrate 110. The third direction D3 may be a direction intersects the first direction D1 and second direction D2. Third direction D3 may be a direction perpendicular to first direction D1 and second direction D2.

In an example embodiment, the second conductivity type doping well region 133 may be formed in at least some regions of the first conductivity type semiconductor layer 120 through ion implantation method. Therefore, the second conductivity type doping well region 133 may be positioned to a predetermined depth from the upper surface to the lower surface of the first conductivity type semiconductor layer 120.

The second conductivity type doping well region 133 may contain SiC. For example, the second conductivity type doping well region 133 may contain 4H SiC. The second conductivity type doping well region 133 may be p-type doped. The second conductivity type doping well region 133 may be p-type doped at a low concentration. The doping concentration of the second conductivity type doping well region 133 may be about 1*10¹⁷ cm⁻³ or more and about 1*10¹⁹ cm⁻³ or less. The material, doping type, doping concentration, and the like of the second conductivity type doping well region 133 are not limited thereto and may be modified in various ways.

The second conductivity type doping layer 135 may be positioned in the second conductivity type doping well region 133. The second conductivity type doping layer 135 may be positioned on the first conductivity type semiconductor layer 120.

In an example embodiment, the thickness along the third direction D3 of the second conductivity type doping layer 135 may be less than the thickness along the third direction D3 of the second conductivity type doping well region 133. The second conductivity type doping layer 135 may have a width narrower than the second conductivity type doping well region 133. That is, the second conductivity type doping layer 135 may be positioned in the second conductivity type doping well region 133. The second conductivity type doping layer 135 may be formed in at least some regions of the second conductivity type doping well region 133 through ion implantation method.

The second conductivity type doping layer 135 may contain SiC. For example, the second conductivity type doping layer 135 may contain 4H SiC. The second conductivity type doping layer 135 may be p-type doped. The second conductivity type doping layer 135 may form an ohmic contact with the source electrode 173. For this purpose, the second conductivity type doping layer 135 may be p-type doped at a high concentration. In an example embodiment, the doping concentration of the second conductivity type doping layer 135 may be higher than the doping concentration of the second conductivity type doping well region 133. The doping concentration of the second conductivity type doping layer 135 may be about 1*10¹⁸ cm⁻³ or more and about 5*10²⁰ cm⁻³ or less. The material, doping type, doping concentration, and the like of the second conductivity type doping layer 135 are not limited thereto and may be modified in various ways.

The first conductivity type doping layer 137 may be positioned in the second conductivity type doping well region 133. The first conductivity type doping layer 137 is positioned at an upper portion of the first conductivity type semiconductor layer 120 and may surround both side surfaces of the second conductivity type doping layer 135. The upper surface of the first conductivity type doping layer 137 may overlap with at least a portion of the gate electrode 151 and at least a portion of the gate insulation layer 141, in the third direction D3. In addition, the upper surface of the first conductivity type doping layer 137 may overlap with at least a portion of the source electrode 173, in the third direction D3, but example embodiments are not limited thereto. The upper surface of the first conductivity type doping layer 137 may directly contact some regions of the gate insulation layer 141.

That is, the first conductivity type doping layer 137 may be positioned in the second conductivity type doping well region 133. At this point, the thickness along the third direction D3 of the first conductivity type doping layer 137 may be less than the thickness along the third direction D3 of the second conductivity type doping well region 133.

The first conductivity type doping layer 137 may be a doping region formed in the first conductivity type semiconductor layer 120 using an ion implantation process. The first conductivity type doping layer 137 may contain SiC. For example, the first conductivity type doping layer 137 may contain 4H SiC. The first conductivity type doping layer 137 may be n-type doped. The first conductivity type doping layer 137 may be p-type doped at a high concentration. The doping concentration of the first conductivity type doping layer 137 may be about 1*10¹⁸ cm⁻³ or more and about 5*10²⁰ cm⁻³ or less. The material, doping type, doping concentration, and the like of the first conductivity type doping layer 137 are not limited thereto and may be modified in various ways.

The gate electrode 151 may be positioned on the first conductivity type semiconductor layer 120. The gate electrode 151 may be separated from the first conductivity type semiconductor layer 120. For example, the gate electrode 151 may be separated from the first conductivity type semiconductor layer 120 in a vertical direction (e.g., the third direction D3) by a gate insulation layer 141.

A semiconductor device according to an example embodiment may have a planar-shaped gate structure. That is, in a semiconductor device according to an example embodiment, the gate electrode 151 has shape of a plate of which an upper surface and a lower surface are flat, and the lower surface of the gate electrode 151 may be positioned at a level higher than the uppermost surface of the first conductivity type semiconductor layer 120. However, example embodiments are not limited thereto, and a semiconductor device according to an example embodiment may have a trench-shaped gate structure. For example, in a semiconductor device according to an example embodiment, a trench of a predetermined depth is formed in a first conductivity type semiconductor layer 120, and the gate electrode 151 may be positioned inside the trench so as to be spaced apart from the first conductivity type semiconductor layer 120 in the third direction D3. Also, the gate electrode 151 may be positioned spaced apart from the first conductivity type semiconductor layer 120 in the horizontal direction (first direction D1 and/or second direction D2).

In an example embodiment, the gate electrode 151 may overlap with the second conductivity type doping well region 133 and the first conductivity type doping layer 137 in the third direction D3. Referring to FIG. 4, the second conductivity type doping well region 133 and the first conductivity type doping layer 137 may partially overlap with the edge region of the gate electrode 151.

The gate electrode 151 may contain one or more conductive materials. For example, the gate electrode 151 may include polysilicon doped with impurities. As another example, the gate electrode 151 may include a metal, a metal alloy, a conductive metal nitride, a metal silicide, a doped semiconductor material, a conductive metal oxide, a conductive metal nitride, or a combination thereof. The gate electrode 151 may be made of a single layer or multiple layers.

The gate insulation layer 141 may be positioned between the first conductivity type semiconductor layer 120 and the gate electrode 151. The gate insulation layer 141 may be positioned under the gate electrode 151 and may cover the lower surface of the gate electrode 151. The gate electrode 151 may be insulated from the first conductivity type semiconductor layer 120 by the gate insulation layer 141. In an example embodiment, the thickness of the gate insulation layer 141 may be almost constant. For example, the thickness of the gate insulation layer 141 may be constant.

The lower surface of the gate insulation layer 141 may be in direct contact with each of the second conductivity type doping well region 133 and the first conductivity type doping layer 137, but example embodiments are not limited thereto. The gate insulation layer 141 may contain an insulating material. For example, the gate insulation layer 141 may contain silicon oxide (SiO2). However, example embodiments are not limited thereto, and the material of the gate insulation layer 141 may be modified in various ways. As another example, the gate insulation layer 141 may contain silicon nitride (SINx), silicon oxynitride (SiON), silicon carbide (SiC), silicon nitride (SiCN) or a combination thereof. The gate insulation layer 141 may be made of a single layer or multiple layers.

The semiconductor device according to an example embodiment may further include a first interlayer insulation layer 142 covering the gate electrode 151. The first interlayer insulation layer 142 may be positioned on the first conductivity type semiconductor layer 120. For example, the first interlayer insulation layer 142 may be positioned on the gate electrode 151. Specifically, the first interlayer insulation layer 142 may cover the upper surface and side surfaces of the gate electrode 151. The first interlayer insulation layer 142 may cover the side surface of the gate insulation layer 141. The first interlayer insulation layer 142 may be positioned on the first conductivity type doping layer 137 too. The first interlayer insulation layer 142 may have a lower surface in contact with at least a portion of the upper surface of the first conductivity type doping layer 137. The gate electrode 151 may be insulated from the source electrode 173 by the first interlayer insulation layer 142.

The first interlayer insulation layer 142 may contain an insulating material. In an example embodiment, the first interlayer insulation layer 142 may contain the same insulating material as the gate insulation layer 141. For example, the first interlayer insulation layer 142 may contain silicon oxide SiO2. However, example embodiments are not limited thereto, and the first interlayer insulation layer 142 may contain various types of insulating materials for insulating the gate electrode 151 from the source electrode 173. For example, the first interlayer insulation layer 142 may include silicon nitride (SiNX), silicon oxynitride (SiON) or a combination thereof. The first interlayer insulation layer 142 may be made of a single layer or multiple layers. When the first interlayer insulation layer 142 is made of the same material as the gate insulation layer 141, the boundary between the first interlayer insulation layer 142 and the gate insulation layer 141 may not be clearly distinguished at a portion where the first interlayer insulation layer 142 contact the gate insulation layer 141.

The source electrode 173 may be positioned on the second conductivity type doping well region 133. A second conductivity type doping layer 135 and a first conductivity type doping layer 137 may be positioned between the source electrode 173 and the second conductivity type doping well region 133. The source electrode 173 may be electrically connected to the second conductivity type doping well region 133 through the second conductivity type doping layer 135. A connection part where the source electrode 173 the second conductivity type doping layer 135 are connected to each other may be positioned at both sides of the gate electrode 151. The first interlayer insulation layer 142 may be positioned between the source electrode 173 and the gate electrode 151. Through the source electrode 173, current or voltage may be provided to the semiconductor device according to an example embodiment. The source electrode 173 may be separated from the gate electrode 151 by the first interlayer insulation layer 142. The source electrode 173 may contact the side surface of the first interlayer insulation layer 142.

The source electrode 173 may contain a conductive material. For example, the source electrode 173 may contain metal, metal alloy, conductive metal nitride, metal silicide, doped semiconductor material, conductive metal oxide, or conductive metal nitrideoxide. For example, the source electrode 173 may contain titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but example embodiments are not limited thereto. The source electrode 173 may be made of a single layer or multiple layers.

A semiconductor device according to an example embodiment may further include a silicide layer positioned between the source electrode 173 and the second conductivity type doping layer 135. The silicide layer may be conformally positioned along an interface between the source electrode 173 and the second conductivity type doping layer 135 and between the source electrode 173 and the first conductivity type doping layer 137. The lower surface of the silicide layer may directly contact the second conductivity type doping layer 135. The upper surface of the silicide layer may be in direct contact with the source electrode 173. The silicide layer may contain a metal silicide material. For example, the silicide layer may contain tungsten silicide (WSi), titanium silicide (TiSi), cobalt silicide (CoSi), nickel silicide (NiSi), or a combination thereof.

A semiconductor device according to an example embodiment may further include a second interlayer insulation layer 143 covering the source electrode 173. The second interlayer insulation layer 143 may protect the detailed components of the semiconductor device according to an example embodiment. Specifically, the second interlayer insulation layer 143 may be a layer that prevents doping regions, conductive electrodes, and the like of from being exposed to oxygen or moisture. The second interlayer insulation layer 143 may be formed with a sufficient thickness to completely cover the doping regions, conductive electrodes, and the like of the semiconductor device.

The second interlayer insulation layer 143 may contain an insulating material. The second interlayer insulation layer 143 may include a material having chemical, mechanical, and high temperature stabilities. For example, the second interlayer insulation layer 143 may be made of a polymer layer such as polyimide (PI), but example embodiments are not limited thereto. The second interlayer insulation layer 143 may further contain various insulating materials such as silicon oxide SiO2, silicon nitride (SINX), silicon oxynitride (SiON), silicon carbide (SiC), silicon nitride (SiCN), or a combination thereof, together with the polymer layer.

The drain electrode 175 may be positioned on the second surface 112, i.e., the lower surface, of the substrate 110. The upper surface of the drain electrode 175 may be in contact with the lower surface of the substrate 110. The drain electrode 175 may be in ohmic contact with the substrate 110. The region in contact with the drain electrode 175 within the substrate 110 may be doped at a relatively high concentration compared to other regions. However, example embodiments are not limited thereto, and another layer may be positioned between the drain electrode 175 and the substrate 110. For example, a silicide layer may be positioned between the drain electrode 175 and the substrate 110. The silicide layer may contain a metal silicide material. An electrical connection between the drain electrode 175 and the substrate 110 may be made by the metal silicide.

The drain electrode 175 may contain conductive material. For example, the drain electrode 175 may contain a metal, a metal alloy, a conductive metal nitride, a metal silicide, a doped semiconductor material, a conductive metal oxide, or a conductive metal nitride. The drain electrode 175 may be made of the same material as the source electrode 173, or may be made of a different material. The drain electrode 175 may be made of single layer or multilayer.

In an example embodiment, a groove 180_1 may be formed on the second surface 112 of the substrate 110. A plurality of grooves 180_1 may be formed on the second surface 112 of substrate 110. For example, the substrate 110 may define the plurality of grooves 180_1. Referring to FIG. 3, each of the plurality of grooves 180_1 may have a shape concavely recessed from the second surface 112 of the substrate 110 toward the first surface 111. In an example embodiment, the depth of each of the plurality of grooves 180_1 may be greater than or equal to about 0.1 μm and less than or equal to about 50 μm.

In an example embodiment, the width along the horizontal direction of each of the plurality of grooves 180_1 may become gradually narrower as being closer to the first surface 111 of the substrate 110. The maximum width along the horizontal direction of each of the plurality of grooves 180_1, for example at the second surface 112, may be greater than or equal to about 0.1 μm and less than or equal to about 50 μm. In an example embodiment, each of the plurality of grooves 180_1 may have a cross-section shape of a pointed triangle toward the first surface 111 of the substrate 110. However, example embodiments are not limited thereto, and each of the plurality of grooves 180_1 may have a rounded surface facing the first surface 111 of the substrate 110.

Each of the plurality of grooves 180_1 may extend long in a direction on the second surface 112 of the substrate 110. In an example embodiment, each of the plurality of grooves 180_1 may extend in substantially the same direction. Each of the plurality of grooves 180_1 may extend long on the second surface 112 of the substrate 110 in a direction parallel to the second surface 112 of the substrate 110. Referring to FIG. 3, each of the plurality of grooves 180_1s may extend in the first direction D1, but example embodiments are not limited thereto. For example, each of the plurality of grooves 180_1 may extend in the second direction D2. For example, each of the plurality of grooves 180_1 may extend in a diagonal direction between the first direction D1 and the second direction D2. The direction in which the plurality of grooves 180_1 extend may vary depending on the direction in which the substrate 110 is warped in the process of manufacturing the semiconductor device according to an example embodiment. For example, if the substrate 110 is warped along the first direction D1, each of the plurality of grooves 180_1 may extend in a direction parallel to the first direction D1 on the second surface 112 of the substrate 110.

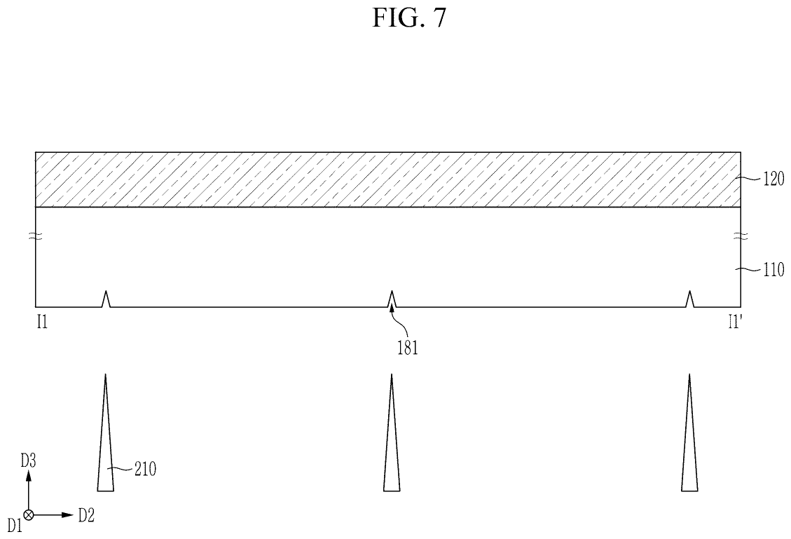

In an example embodiment, the plurality of grooves 180_1 may be positioned on the second surface 112 of the substrate 110, so as to be spaced apart from each other in a direction perpendicular to the direction in which the plurality of grooves 180_1 extend. In an example embodiment, the spacing (i.e., pitch) between the plurality of grooves 180_1 may be constant. This may be due to the process characteristic of simultaneously forming the plurality of grooves 180_1 on the second surface 112 of the substrate 110 by using a plurality of tips spaced at regular intervals. This will be described in detail referring to FIG. 7 to FIG. 20. In an example embodiment, the spacing between the plurality of grooves 180_1 may be substantially the same as the spacing between the plurality of tips used for forming the grooves 180_1 on the substrate 110. In an example embodiment, the spacing between the plurality of grooves 180_1 may be greater than or equal to about 0.1 mm and less than or equal to about 10 mm.

The plurality of grooves 180_1 extending in different directions may be formed on the second surface 112 of the substrate 110. For example, on the second surface 112 of the substrate 110, a plurality of grooves 180_1 extending in the first direction D1 and a plurality of grooves 180_1 extending in a direction intersecting the first direction D1 may be formed together. In this case, the plurality of grooves 180_1 positioned on the second surface 112 of the substrate 110 may form a lattice pattern, when viewed in a plan view.

In an example embodiment, the plurality of grooves 180_1 formed on the second surface 112 of the substrate 110 may be filled by the drain electrode 175. In this regard, the drain electrode 175 may extend into each of the plurality of grooves 180_1. This may be due to the process characteristic of forming the drain electrode 175 on the second surface 112 of the substrate 110 after forming the grooves 180_1 on the second surface 112 of the substrate 110.

The drain electrode 175 may include a third surface 113 facing the second surface 112 of the substrate 110, and a fourth surface 114 facing the third surface 113. The third surface 113 of the drain electrode 175 may be an upper surface, and the fourth surface 114 of the drain electrode 175 may be a lower surface. In an example embodiment, a plurality of grooves 180_2 may be formed on the fourth surface 114 of the drain electrode 175. For example, the drain electrode 175 may define the plurality of grooves 180_2.

The specific shape and extending direction of the plurality of grooves 180_2 formed on the fourth surface 114 of the drain electrode 175, the spacing between the plurality of grooves 180_2, and the like are the same as those of the plurality of grooves 180_1 formed on the second surface 112 of the substrate 110 described above, and therefore, a detailed description thereof will be omitted.

Referring to FIG. 3, the plurality of grooves (180_1, 180_2) are formed on the second surface 112 of the substrate 110 and the fourth surface 114 of the drain electrode 175, respectively. However, alternatively, the plurality of grooves (180_1, 180_2) may be formed on only one of the second surface 112 of the substrate 110 and the drain electrode 175. For example, the grooves 180_1 are formed only on the second surface 112 of the substrate 110, and the grooves 180_2 may not be formed on the fourth surface 114 of the drain electrode 175. For example, the grooves 180_1 may not be formed on the second surface 112 of the substrate 110, and the grooves 180_2 may be formed only on the fourth surface 114 of the drain electrode 175.

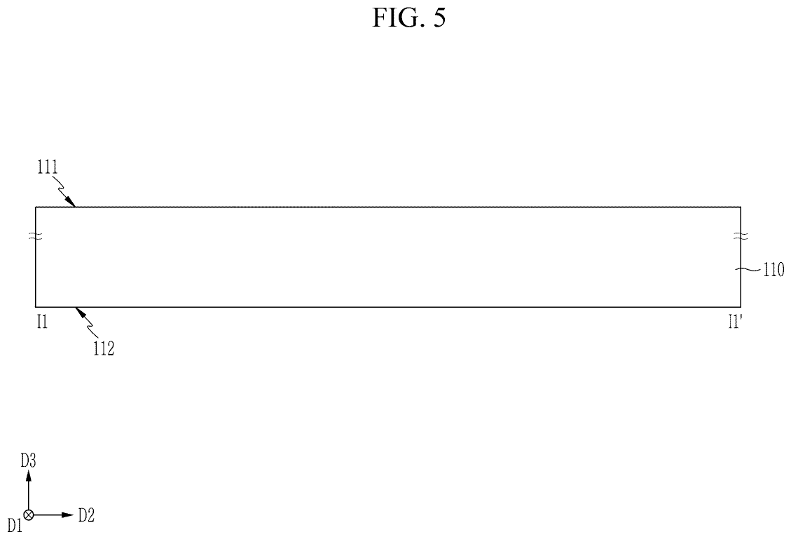

FIG. 5 to FIG. 20 are process cross-sectional views to explain a manufacturing process of a semiconductor device according to example embodiment.

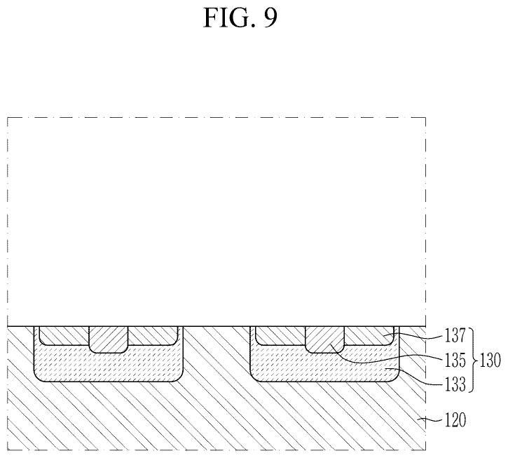

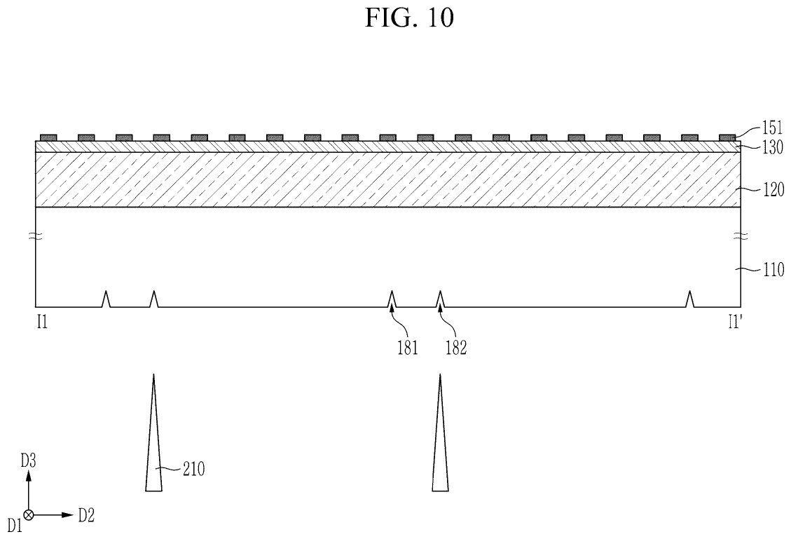

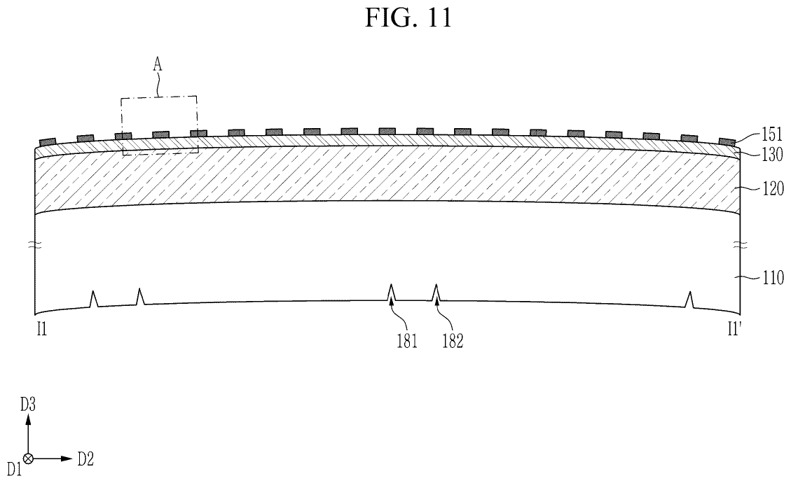

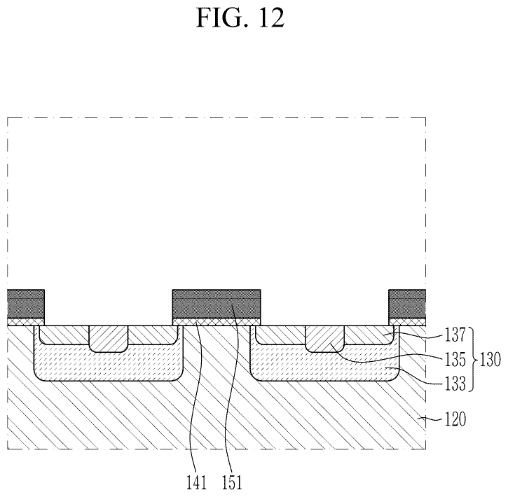

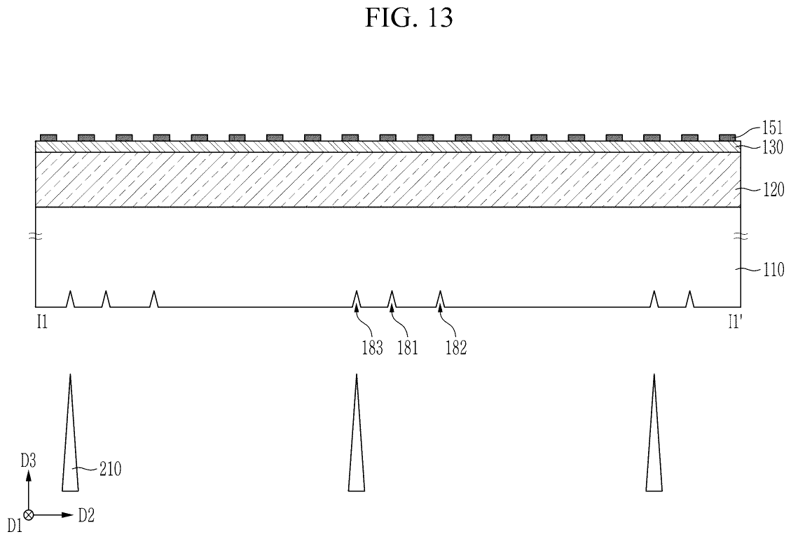

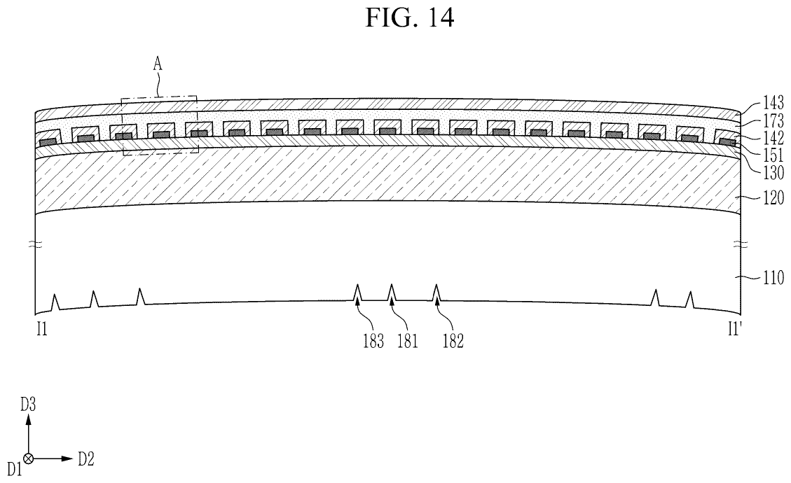

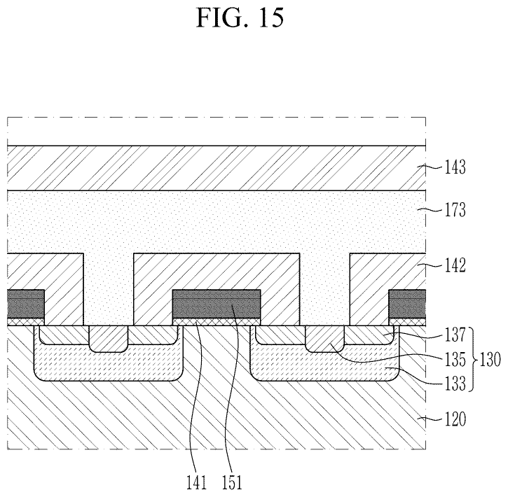

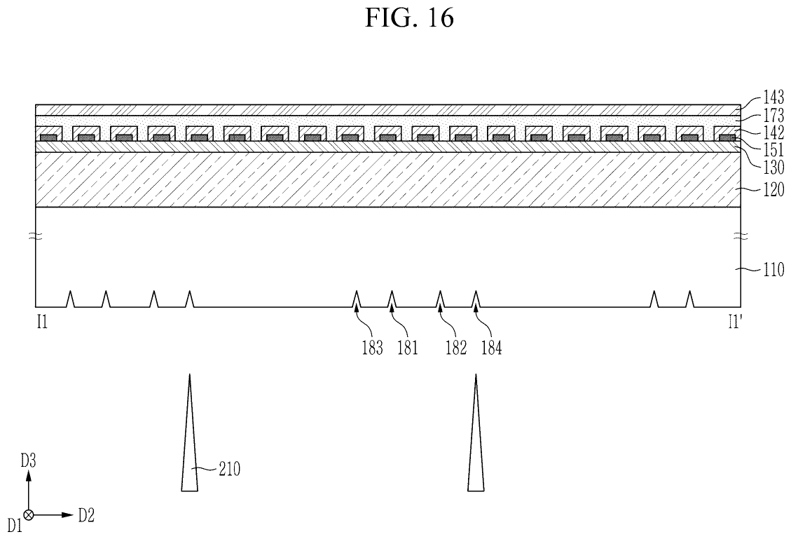

FIG. 5 to FIG. 8, FIG. 10, FIG. 11, FIG. 13, FIG. 14, and FIG. 16 to FIG. 20 are cross-sectional views corresponding to regions cut along line I1-I1′ of FIG. 1, for explaining a method for manufacturing a semiconductor device according to an example embodiment. FIG. 9, FIG. 12, and FIG. 15 are cross-sectional views corresponding to the ‘A’ region of FIG. 2, for explaining a method for manufacturing a semiconductor device according to an example embodiment.

As illustrated in FIG. 5, a substrate 110 for manufacturing a semiconductor device according to an example embodiment may be provided. The substrate 110 may include a first surface 111 and a second surface 112 opposite the first surface 111. The substrate 110 illustrated in FIG. 5 may be a bare substrate 110. In an example embodiment, in the bare substrate 110, the internal residual stress may be substantially the same throughout the entire volume, and thus the substrate 110 may be planar with no or very little warpage. The bare substrate 110 may have a first surface 111 and a second surface 112 in a flat state. In an example embodiment, the substrate 110 may be n-type doped.

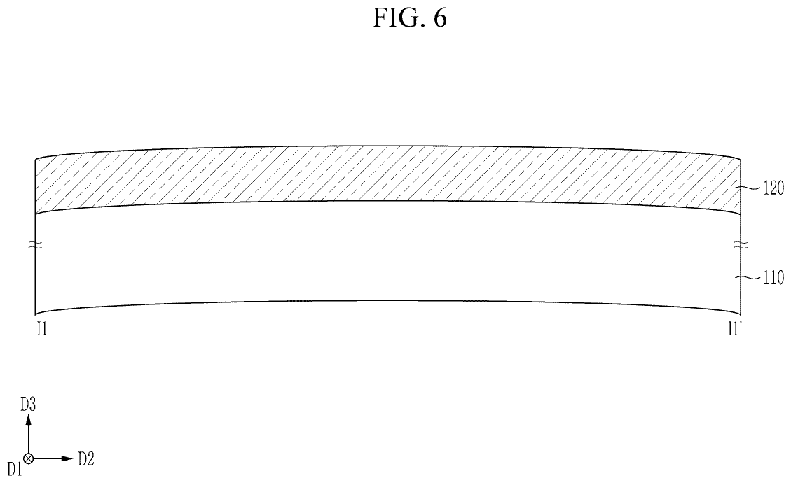

As illustrated in FIG. 6, a first conductivity type semiconductor layer 120 may be formed on the first surface 111 of the substrate 110 using an epitaxial growth method. At this time, the first conductivity type semiconductor layer 120 may be formed directly on the substrate 110, or another layer may be formed on the substrate 110, and then the first conductivity type semiconductor layer 120 may be formed on the other layer.

The first conductivity type semiconductor layer 120 may contain SiC. For example, the first conductivity type semiconductor layer 120 may contain 4H SiC. The first conductivity type semiconductor layer 120 may be n-type doped at a low concentration. The doping type of the first conductivity type semiconductor layer 120 may be the same as the doping type of the substrate 110. The doping material of the first conductivity type semiconductor layer 120 may be the same as or different from the doping material of the substrate 110. The doping concentration of the first conductivity type semiconductor layer 120 may be lower than the doping concentration of the substrate 110.

In an example embodiment, the first conductivity type semiconductor layer 120 and the substrate 110 may have different lattice constants. For example, the lattice constant of the first conductivity type semiconductor layer 120 may be greater than the lattice constant of the substrate 110. In this case, after forming the first conductivity type semiconductor layer 120 on the first surface 111 of the substrate 110, the residual stresses at the first surface 111 and the second surface 112 of the substrate 110 may become different from each other, and thus, a warpage may occur in the substrate 110. For example, the substrate 110 may be deformed convexly with respect to the first surface 111, and in this case, the substrate 110 may be warped into a shape roughly similar to the alphabet ‘U’ flipped upside down, as shown in FIG. 6.

As shown in FIG. 6, if warpage occurs in the substrate 110, in subsequent processes, for example, in doping process or in thin film process, doping layers or thin films may not be accurately formed at the target region and may become vulnerable to physical impact. Accordingly, in each process for manufacturing a semiconductor device according to example embodiments, it is important to control the warpage of the substrate 110.

In order to control the warpage of the substrate 110 in an example embodiment, a plurality of first grooves 181 may be formed on the second surface 112 of the substrate 110, as illustrated in FIG. 7. When the warpage occurs in the substrate 110 in the shape as shown in FIG. 6, the warpage of the substrate 110 can be alleviated if the plurality of first grooves 181 are formed on the second surface 112 of the substrate 110. Specifically, when a plurality of first grooves 181 are formed on the second surface 112 of the substrate 110 as shown in FIG. 7, the substrate 110 may be deformed convexly with respect to the second surface 112 by the Twyman effect. In this case, the substrate 110 may be deformed concavely with respect to a direction opposite to the direction in which the substrate 110 is warped as described with reference to FIG. 6, and thus the warpage formed in the substrate 110 can be alleviated.

In an example embodiment, the process of forming first grooves 181 on the second surface 112 of the substrate 110 may be performed by a groove forming member (i.e., groove forming device) 210. To form a groove on the second surface 112 of the substrate 110, a plurality of tips included in the groove forming member 210 may be brought into contact with the second surface 112 of the substrate 110, and a predetermined pressure may be applied. Then, by moving the groove forming member 210 in a direction, the plurality of first grooves 181 may be formed on the second surface 112 of the substrate 110. In another example embodiment, the groove forming member 210 may include a plurality of blades instead of a plurality of tips.

A plurality of first grooves 181 may be formed simultaneously. In an example embodiment, the groove forming member 210 may include a plurality of tips arranged spaced apart in a direction, and the plurality of tips simultaneously contact the second surface 112 of the substrate 110, and then the groove forming member 210 may be moved in a direction. Accordingly, the plurality of first grooves 181 may be formed simultaneously on the second surface 112 of the substrate 110.

In an example embodiment, the plurality of tips included in the groove forming member 210 may be arranged at regular intervals along a direction. In an example embodiment, the spacing between the tips may be, for example, greater than or equal to 0.1 mm and less than or equal to 10 mm.

In an example embodiment, the groove forming member 210 may contain a material having a hardness higher than SiC. For example, the groove forming member 210 (i.e., the tips or blades) may contain diamond.

In an example embodiment, for forming the grooves on the second surface 112 of the substrate 110, the direction in which the groove forming member 210 moves may be determined depending on the direction in which the substrate 110 is warped. For example, if the substrate 110 is warped along the first direction D1 as illustrated in FIG. 6, the plurality of tips included in the groove forming member 210 may be brought into contact with the second surface 112 of the substrate 110 and then may be moved along a direction parallel to the first direction D1. As another example, when the substrate 110 is warped along the second direction D2, the plurality of tips included in the groove forming member 210 may be brought into contact with the second surface 112 of the substrate 110 and then may be moved along a direction parallel to the second direction D2. For example, when the substrate 110 is warped along a diagonal direction between the first direction D1 and the second direction D2, the plurality of tips included in the groove forming member 210 may be brought into contact with the second surface 112 of the substrate 110 and then may be moved along a direction parallel to the diagonal direction.

In an example embodiment, the plurality of first grooves 181 may be formed in two or more directions on the second surface 112 of the substrate 110. For example, when the substrate 110 is warped along the first direction D1 and a direction intersecting the first direction D1 (e.g., second direction D2), the first grooves 181 may be formed along a direction parallel to the first direction D1 and a direction parallel to a direction intersecting the first direction D1.

In an example embodiment, a process of measuring the warpage of the substrate 110 may be performed before performing a process of forming the first groove 181, and a direction for forming the first grooves 181 on the second surface 112 of the substrate 110 may be determined based on the warpage of the substrate 110. For example, as described with reference to FIG. 6, after forming a first conductivity type semiconductor layer 120 on the substrate 110 and before forming the first grooves 181 on the second surface 112 of the substrate 110, the warpage of the substrate 110 may be measured. In an example embodiment, after measuring the warpage of the substrate 110, the direction for forming the first groove 181 on the second surface 112 of the substrate 110 may be determined based on the measurement result. The process of measuring the warpage of substrate 110 may be performed by various methods. In an example embodiment, if the substrate 110 is not warped or the degree of warpage is very small (i.e., below a threshold) when the warpage of the substrate 110 is measured, the process of forming the plurality of first grooves 181 on the second surface 112 of the substrate 110 may be omitted.

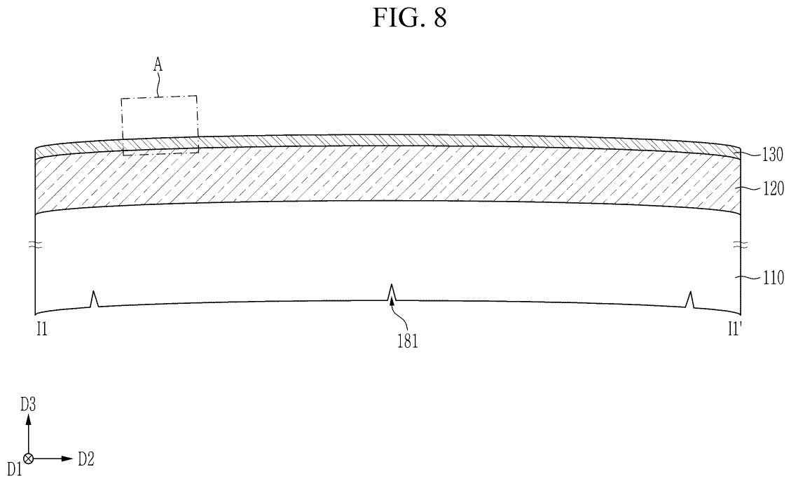

Referring to FIG. 8 and FIG. 9, after alleviating the warpage of the substrate 110, a doping layer 130 including a second conductivity type doping well region 133, a first conductivity type doping layer 137, and a second conductivity type doping layer 135 may be formed on the first conductivity type semiconductor layer 120. Specifically, the second conductivity type doping well region 133, the first conductivity type doping layer 137, and the second conductivity type doping layer 135 may be sequentially formed on the first conductivity type semiconductor layer 120.

The second conductivity type doping well region 133 may be formed at an upper region of the first conductivity type semiconductor layer 120. The second conductivity type doping well region 133 may be formed by an ion implantation process (IIP). Using a photolithography process, a region where a second conductivity type doping well region 133 is formed may be defined on a first conductivity type semiconductor layer 120. Second conductivity type impurity ions may be implanted into the corresponding region. The second conductivity type doping well region 133 may have a predetermined depth. At this time, the depth of the second conductivity type doping well region 133 may be determined by the number of ions to be implanted and/or the speed at which the ions are accelerated.

In an example embodiment, the second conductivity type doping well region 133 may contain SiC. For example, the second conductivity type doping well region 133 may contain 4H SiC. The second conductivity type doping well region 133 may be p-type doped. The second conductivity type doping well region 133 may be p-type doped at a low concentration. For example, the doping concentration of the second conductivity type doping well region 133 may be about 1*10¹⁷ cm⁻³ or more and about 1*10¹⁹ cm⁻³ or less. The material, doping type, doping concentration, and the like of the second conductivity type doping well region 133 are not limited thereto and may be modified in various ways.

The first conductivity type doping layer 137 may be formed by implanting ions into the second conductivity type doping well region 133. The first conductivity type doping layer 137 may be formed in the second conductivity type doping well region 133 through an ion implantation process. The first conductivity type doping layer 137 may be formed in at least some regions of the second conductivity type doping well region 133. For example, the first conductivity type doping layer 137 may be formed to a predetermined depth from the upper surface of the second conductivity type doping well region 133.

The first conductivity type doping layer 137 may contain SiC. For example, the first conductivity type doping layer 137 may contain 4H SiC. The first conductivity type doping layer 137 may be p-type doped at high concentration. The doping type of the first conductivity type doping layer 137 may be different from the doping type of the second conductivity type doping well region 133. The doping type of the first conductivity type doping layer 137 may be the same as the doping types of the substrate 110 and the first conductivity type semiconductor layer 120. The doping concentration of the first conductivity type doping layer 137 may be about 1*10¹⁸ cm⁻³ or more and about 5*10²⁰ cm⁻³ or less. The material, doping type, doping concentration, and the like of the first conductivity type doping layer 137 are not limited thereto and may be modified in various ways.

The second conductivity type doping layer 135 may further formed by implanting ions into the second conductivity type doping well region 133 and the first conductivity type doping layer 137. Using a photolithography process, a region where a second conductivity type doping layer 135 is formed may be defined on a first conductivity type doping layer 137. The region where the second conductivity type doping layer 135 is formed may have a width less than the second conductivity type doping well region 133 or the first conductivity type doping layer 137. In an example embodiment, the depth at which the second conductivity type doping layer 135 is formed may be deeper than the depth of the first conductivity type doping layer 137. The second conductivity type doping layer 135 may penetrate the first conductivity type doping layer 137 in the thickness direction. At least some regions of both side surfaces of the second conductivity type doping layer 135 may be surrounded by the first conductivity type doping layer 137.

The second conductivity type doping layer 135 may contain SiC. For example, the second conductivity type doping layer 135 may contain 4H SiC. The second conductivity type doping layer 135 may be p-type doped at a high concentration. The doping type of the second conductivity type doping layer 135 may be the same as the doping type of the second conductivity type doping well region 133. The doping material of the second conductivity type doping layer 135 may be the same as or different from the doping material of the second conductivity type doping well region 133. The doping concentration of the second conductivity type doping layer 135 may be higher than the doping concentration of the second conductivity type doping well region 133.

In an example embodiment, the second conductivity type doping well region 133, the second conductivity type doping layer 135, and the first conductivity type doping layer 137 may be formed by an ion implantation process (IIP). When a plurality of ions collide with the surface of the first conductivity type semiconductor layer 120, lattices of the surface of the first conductivity type semiconductor layer 120 may be damaged, and residual stress at the surface of the first conductivity type semiconductor layer 120 may be increased. Accordingly, warpage may occur in the substrate 110 as shown in FIG. 8 due to the difference in the residual stresses at the surface of the first conductivity type semiconductor layer 120 and the residual stress at the second surface 112 of the substrate 110.

As illustrated in FIG. 10, a plurality of second grooves 182 may be formed on the second surface 112 of the substrate 110. When the warpage occurs in the substrate 110 in the shape as shown in FIG. 8, the warpage of the substrate 110 can be alleviated if the plurality of second grooves 182 are formed on the second surface 112 of the substrate 110.

In an example embodiment, the process of forming second grooves 182 on the second surface 112 of the substrate 110 may be performed by the groove forming member 210. The specific method of forming the second grooves 182 by the groove forming member 210 is the same as the process of forming the first grooves 181 described above, so a detailed description will be omitted.

In an example embodiment, the direction in which the second groove 182 extends may be determined depending on the direction in which the substrate 110 is warped in the process described with reference to FIG. 8 and FIG. 9. Referring to FIG. 8 and FIG. 10, it is illustrated that the substrate 110 is warped along the first direction D1 and thus a plurality of second grooves 182 extend along the first direction D1, but this is provided as an example, and the direction in which the substrate 110 is warped and the direction in which the second grooves 182 extend may be variously modified depending on the aspect in which the doping layer 130 is formed.

Referring to FIG. 10, the second grooves 182 are illustrated as not overlapping the first grooves 181, but the second grooves 182 may overlap the first grooves 181. For example, the second grooves 182 may be formed on the second surface 112 on which the first grooves 181 of the substrate 110 are formed. In this case, the depth of the plurality of grooves 181 and 182 formed on the second surface 112 of the substrate 110 may be deeper than shown in FIG. 10.

In an example embodiment, for determining a direction for forming the second grooves 182 on the second surface 112 of the substrate 110, a process of measuring the warpage of the substrate 110 may be performed before performing a process of forming the second groove 182. At this time, if the substrate 110 is not warped or the degree of warpage is very small (i.e., below a threshold), the process of forming a plurality of second grooves 182 on the second surface 112 of the substrate 110 may be omitted.

As shown in FIG. 11 and FIG. 12, a gate insulation layer 141 may be formed on the first conductivity type semiconductor layer 120, and a gate electrode 151 may be formed on the gate insulation layer 141. In an example embodiment, the gate insulation layer 141 and the gate electrode 151 may also be partially positioned on the second conductivity type doping well region 133 and the first conductivity type doping layer 137. A gate insulating material layer may be formed on the entire area of the upper surfaces of the first conductivity type semiconductor layer 120, the second conductivity type doping well region 133, the first conductivity type doping layer 137, and the second conductivity type doping layer 135. The gate insulating material layer may be formed by a high temperature oxidation process. A gate material layer may be formed by depositing polysilicon on the gate insulating material layer. The gate insulation layer 141 and the gate electrode 151 may be formed by etching a portion of the gate insulating material layer and the gate material layer. At this time, a portion of the upper surface of the first conductivity type semiconductor layer 120, the second conductivity type doping layer 135, and the first conductivity type doping layer 137 may be exposed.

In the process of forming the gate insulation layer 141 and the gate electrode 151, the warpage may occur in the substrate 110. This may be due to the difference in lattice constants of the gate insulation layer 141 and the first conductivity type semiconductor layer 120 or the gate insulation layer 141 and the doping layer 130, and the resulting difference in residual stresses at the front surface and the rear surface of the semiconductor device.

As illustrated in FIG. 13, a plurality of third grooves 183 may be formed on the second surface 112 of the substrate 110. When the warpage occurs in the substrate 110 in the shape as shown in FIG. 11, the warpage of the substrate 110 can be alleviated if the plurality of first grooves 181 are formed on the third surface 113 of the substrate 110.

In an example embodiment, the process of forming third grooves 183 on the second surface 112 of the substrate 110 may be performed by the groove forming member 210. The detailed descriptions of this will be omitted.

In an example embodiment, the direction in which the third groove 183 extends may be determined depending on the direction in which the substrate 110 is warped in the process described with reference to FIG. 11 and FIG. 12. Referring to FIG. 11 and FIG. 13, it is illustrated that the substrate 110 is warped along the first direction D1 and thus a plurality of third grooves 183 extend along the first direction D1, but this is provided as an example, and the direction in which the substrate 110 is warped and the direction in which the third grooves 183 extend may be variously modified depending on the aspect in which the gate insulation layer 141 and the gate electrode 151 are formed.

Referring to FIG. 13, the third grooves 183 are illustrated as not overlapping the first groove 181 and the second grooves 182, but the third grooves 183 may overlap the first grooves 181 or the second grooves 182. In an example embodiment, a process of measuring the warpage of the substrate 110 may be performed before performing a process of forming the third grooves 183 on the second surface 112 of the substrate 110. At this time, if the substrate 110 is not warped or the degree of warpage is very small (i.e., below a threshold), the process of forming a plurality of third grooves 183 on the second surface 112 of the substrate 110 may be omitted.

As illustrated in FIG. 14 and FIG. 15, a first interlayer insulation layer 142 covering the gate electrode 151 and the gate insulation layer 141 may be formed. The first interlayer insulation layer 142 may also cover the upper surface of the second conductivity type doping layer 135 and some regions of the upper surface of the first conductivity type doping layer 137. The first interlayer insulation layer 142 may contain silicon oxide SiO2. However, example embodiments are not limited thereto, and the material of the first interlayer insulation layer 142 may be modified in various ways. As another example, the first interlayer insulation layer 142 may contain silicon nitride (SiNX), silicon oxynitride (SiON), silicon carbide (SiC), silicon carbon nitride (SiCN) or a combination thereof. However, the formation method and material of the first interlayer insulation layer 142 are not limited thereto and may be modified in various ways.

A source electrode 173 covering a portion of the first interlayer insulation layer 142 and the doping layer 130 may be formed, and a second interlayer insulation layer 143 may be formed on the source electrode 173. The source electrode 173 may cover the upper surface and the side surface of the first interlayer insulation layer 142. The source electrode 173 may contact at least some regions of the upper surface of the second conductivity type doping layer 135 and the upper surface of the first conductivity type doping layer 137. The source electrode 173 may contain a conductive material. For example, the source electrode 173 may contain conductive materials, including at least one of titanium (Ti), aluminum (Al), silver (Ag), nickel (Ni), and nickel vanadium (NIV), but, example embodiments are not limited thereto and the source electrode 173 may contain various conductive materials.

The second interlayer insulation layer 143 may cover the source electrode 173. The second interlayer insulation layer 143 may contain an insulating material. For example, the second interlayer insulation layer 143 may be made of a polymer layer such as polyimide (PI), but example embodiments are not limited thereto.

In the process of forming the first interlayer insulation layer 142, the source electrode 173, and the second interlayer insulation layer 143, the warpage may occur in the substrate 110. This may be due to the difference in lattice constants of the first interlayer insulation layer 142 and the doping layer 130 and the source electrode 173 covering them, and the resulting difference in residual stresses at the front surface and rear surface of the semiconductor device.

As illustrated in FIG. 16, a plurality of fourth grooves 184 may be formed on the second surface 112 of the substrate 110. When the warpage occurs in the substrate 110 in the shape as shown in FIG. 14, the warpage of the substrate 110 can be alleviated if the plurality of fourth grooves 184 are formed on the second surface 112 of the substrate 110.

In an example embodiment, the process of forming fourth grooves 184 on the second surface 112 of the substrate 110 may be performed by the groove forming member 210. The detailed descriptions of this will be omitted.

In an example embodiment, the direction in which the fourth grooves 184 extends may be determined depending on the direction in which the substrate 110 is warped in the process described with reference to FIG. 14 and FIG. 15. Referring to FIG. 14 and FIG. 16, it is illustrated that the substrate 110 is warped along the first direction D1 and thus a plurality of fourth grooves 184 extend along the first direction D1, but this is provided as an example, and the direction in which the substrate 110 is warped and the direction in which the fourth grooves 184 extend may be variously modified depending on the aspect in which the first interlayer insulation layer 142, the source electrode 173, and the second interlayer insulation layer 143 are formed.

In some example embodiments, the fourth grooves 184 may overlap the first grooves 181, the second grooves 182, or the third grooves 183. In an example embodiment, a process of measuring the warpage of the substrate 110 may be performed before performing a process of forming the fourth grooves 184 on the second surface 112 of the substrate 110. At this time, if the substrate 110 is not warped or degree of warpage is a very small (i.e., below a threshold), the process of forming a plurality of fourth grooves 184 may be omitted.

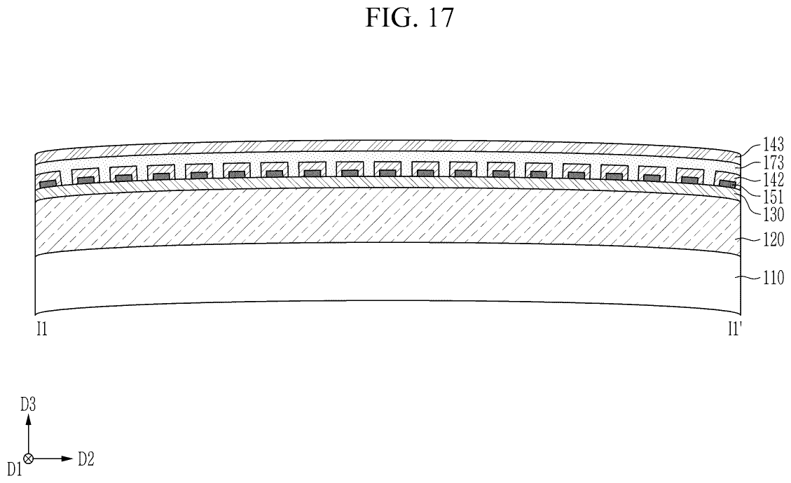

As illustrated in FIG. 17, a process of thinning the substrate 110 may be performed. The process of thinning the substrate 110 may be a process of decreasing the thickness of the substrate 110 by performing a grinding and/or chemical mechanical polishing (CMP) process on the second surface 112 of the substrate 110. After performing the thinning process, the substrate 110 may have a thickness of about 20 μm to about 500 μm. Referring to FIG. 17, as the substrate 110 is thinned, at least some of the plurality of grooves 181, 182, 183 and 184 formed on the second surface 112 of the substrate 110 may be removed.

In an example embodiment, by the process of thinning the substrate 110, the warpage in the substrate 110 into a shape as shown in FIG. 17 may occur.

The relationship between the stress and warpage inside a thin film may be expressed as [Equation 1] below.

$${σ}_{f} = \frac{{E}_{S} \cdot {t}_{S}^{2}}{6 \cdot ( 1 - {v}_{S} ) \cdot {t}_{f}} \cdot \frac{1}{R} \qquad [ Equation 1 ]$$

In [Equation 1], σ_{f} is the internal stress of the thin film, Eₛ is the elasticity coefficient of the substrate, tₛ is the thickness of the substrate, vₛ is the Poisson's ratio of the substrate, t_{f} is the thickness of the thin film, and R is the curvature radius of the substrate after a thin film is deposited.

In [Equation 1], assuming other conditions are the same, the curvature radius R of the substrate may be inversely proportional to the square of the thickness tₛ of the substrate. In this regard, for the same magnitude of internal stress, the substrate may be warped better when the substrate is thin than when the substrate is thick.

The residual stress at the front surface of the semiconductor device according to an example embodiment may be the same before and after performing the thinning process. As described with reference to FIG. 17, the thickness of the substrate 110 may be reduced by the thinning process, and thus, the warpage may occur in the substrate 110 as illustrated in FIG. 17.

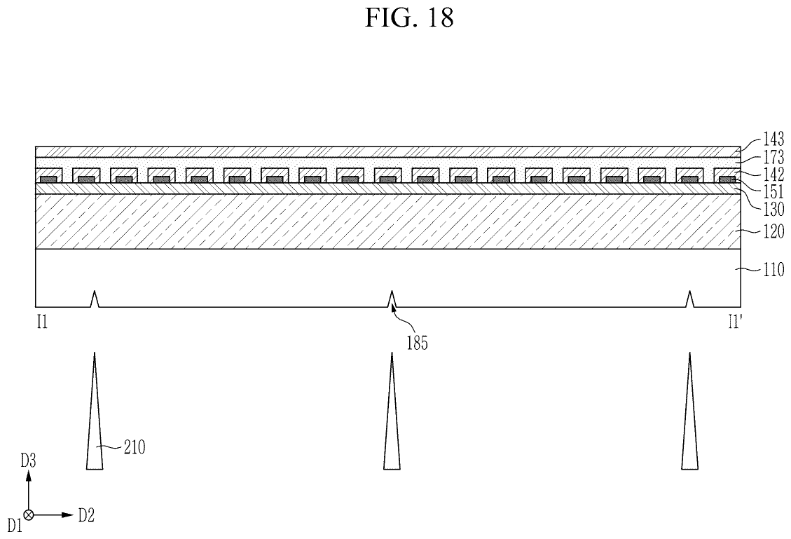

As illustrated in FIG. 18, a plurality of fifth grooves 185 may be formed on the second surface 112 of the substrate 110. When the warpage occurs in the substrate 110 in the shape as shown in FIG. 15, the warpage of the substrate 110 can be alleviated if the plurality of fifth grooves 185 are formed on the second surface 112 of the substrate 110.

In an example embodiment, the process of forming fifth grooves 185 on the second surface 112 of the substrate 110 may be performed by the groove forming member 210. The detailed descriptions of this will be omitted.

Referring to FIG. 18, the fifth groove 185 is shown as extending in the first direction D1, but this is provided as an example, and the direction in which the fifth groove 185 extends may be variously modified depending on the direction in which the substrate 110 is warped in the process described with reference to FIG. 17.

In an example embodiment, a process of measuring the warpage of the substrate 110 may be performed before performing a process of forming the fifth grooves 185 on the second surface 112 of the substrate 110. At this time, if the substrate 110 is not warped or degree of warpage is a very small (i.e., below a threshold), the process of forming a plurality of fifth grooves 185 may be omitted.

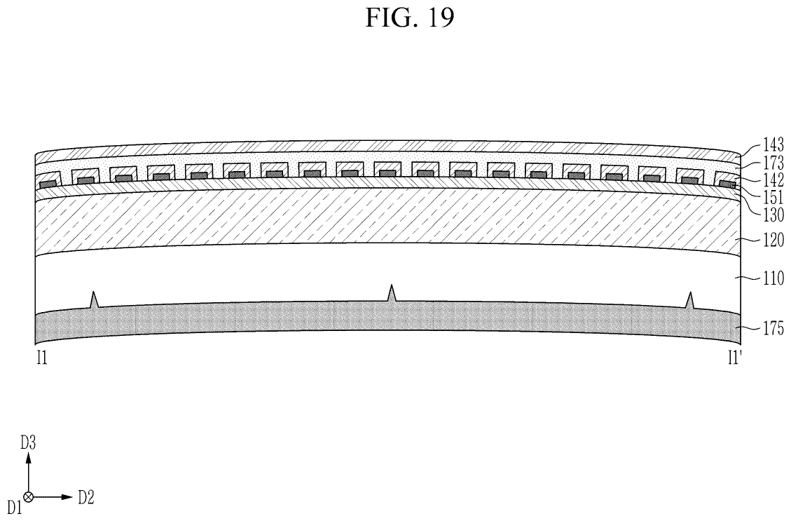

Referring to FIG. 19, a drain electrode 175 may be formed on the second surface 112 of the substrate 110. The drain electrode 175 may cover the entire second surface 112 of the substrate 110. However, example embodiments are not limited thereto, and the drain electrode 175 may cover only a portion of the second surface 112 of the substrate 110. The drain electrode 175 may contain conductive material. The drain electrode 175 may be made of the same material as the source electrode 173, or may be made of a different material. For example, the drain electrode 175 may contain at least one of titanium (Ti), aluminum (Al), silver (Ag), nickel (Ni), nickel vanadium (NiV), gold (Au), and platinum (Pt), but example embodiments are not limited thereto, and may contain various conductive materials.

In the process of forming the drain electrode 175, the warpage may occur in the substrate 110. This may be due to the difference in lattice constants of the drain electrode 175 and the substrate 110 and the resulting difference in residual stress at the front surface and the rear surface of the semiconductor device.

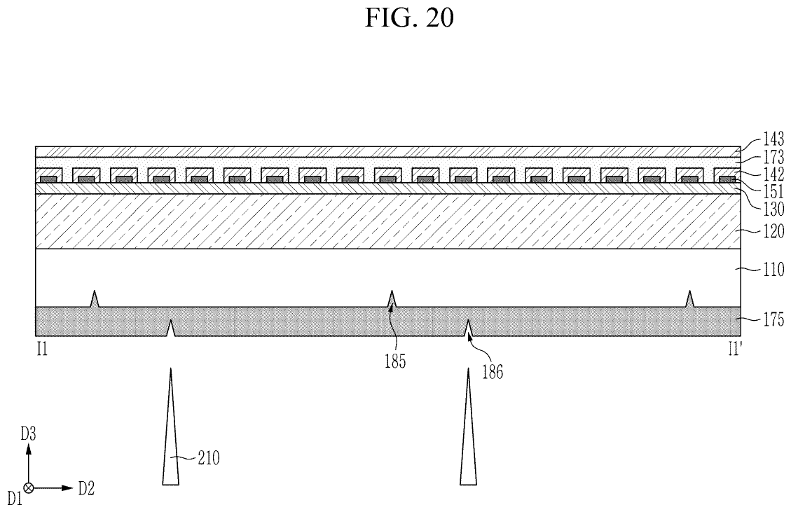

As illustrated in FIG. 20, a plurality of sixth grooves 186 may be formed on the second surface 112 of the substrate 110. When the warpage occurs in the substrate 110 in the shape as shown in FIG. 19, the warpage of the substrate 110 can be alleviated if the plurality of sixth grooves 186 are formed on the second surface 112 of the substrate 110.

In an example embodiment, the process of forming sixth grooves 186 on the second surface 112 of the substrate 110 may be performed by the groove forming member 210. The detailed descriptions of this will be omitted.

In an example embodiment, the direction in which the sixth groove 186 extends may be determined depending on the direction in which the substrate 110 is warped in the process described with reference to FIG. 19. Referring to FIG. 20, the sixth groove 186 is shown as extending in the first direction D1, but this is provided as an example, and the direction in which the sixth groove 186 extends may be variously modified depending on the direction in which the substrate 110 is warped in the process described with reference to FIG. 19.

In some example embodiments, the sixth grooves 186 may overlap the fifth grooves 185. In an example embodiment, a process of measuring the warpage of the substrate 110 may be performed before performing a process of forming the sixth grooves 186 on the second surface 112 of the substrate 110. At this time, if the substrate 110 is not warped or degree of warpage is a very small (i.e., below a threshold), the process of forming a plurality of sixth grooves 186 may be omitted.

In example embodiments, it is described that, after forming a first conductivity type semiconductor layer 120, forming a doping layer 130, forming a gate insulation layer 141 and a gate electrode 151, forming a source electrode 173, the first interlayer insulation layer 142 and the second interlayer insulation layer 143, forming a substrate 110 into a thin film, and forming a drain electrode 175, the warpage of the substrate 110 is measured, and, according to that, grooves 180 are formed on the rear surface of the substrate 110 or the drain electrode 175, but this is provided as an example, and example embodiments are not limited thereto. For example, among the processes described above, the process of measuring the warpage of substrate 110 and the process of forming grooves 180 may be omitted.

For example, a process of measuring the warpage of substrate 110 and a process of forming grooves 180 may be added in some processes. For example, in the process of forming the doping layer 130, the process of measuring the warpage of the substrate 110 and the process of forming the grooves 180 may be performed each time the process of forming each of the doping layers 133, 135, and 137 is completed. For example, each time the process of forming the source electrode 173, the process of forming the first interlayer insulation layer 142, and the process of forming the second interlayer insulation layer 143 are completed, the process of measuring the warpage of the substrate 110 and the process of forming the grooves 180 may be performed.

According to example embodiments, the warpage occurring in a substrate 110 during the manufacturing processes of a semiconductor device can be alleviated, and thus, the reliability of the manufacturing process of the semiconductor device and the semiconductor device manufactured thereby can be improved.

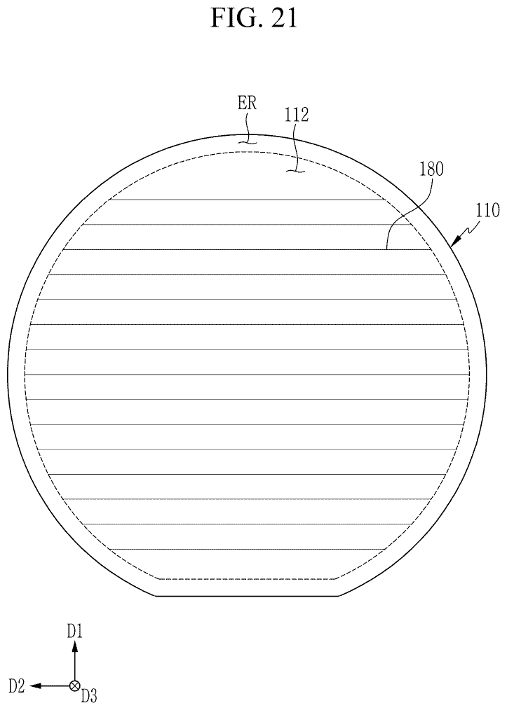

FIG. 21 to FIG. 31 are drawings illustrating semiconductor devices according to various example embodiments. FIG. 21 to FIG. 31 are drawings illustrating the second surface 112 of the substrate 110 of a semiconductor device according to an example embodiment. FIG. 21 to FIG. 31 may illustrate the second surface 112 of the substrate 110 at one of the manufacturing processes of the semiconductor device described with reference to FIG. 5 to FIG. 20.

The substrate 110 illustrated in FIG. 21 may be warped along the second direction D2. Accordingly, the grooves 180 formed on the second surface 112 of the substrate 110 may extend along a direction parallel to the second direction D2.

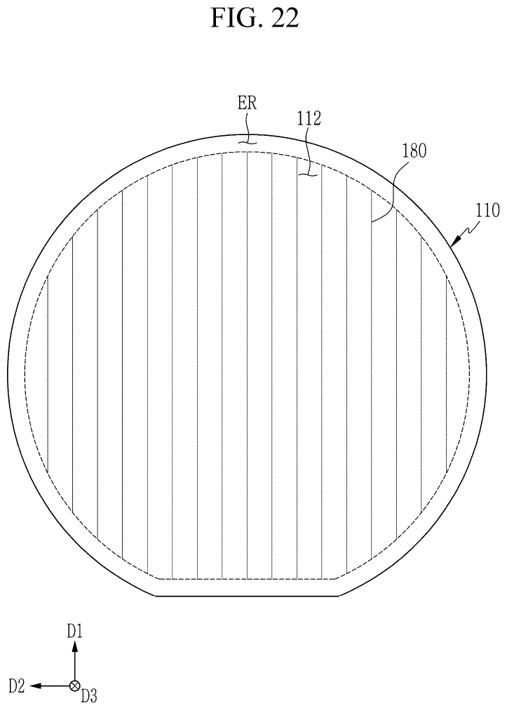

The substrate 110 illustrated in FIG. 22 may be warped along the first direction D1. Accordingly, the grooves 180 formed on the second surface 112 of the substrate 110 may extend along a direction parallel to the first direction D1.

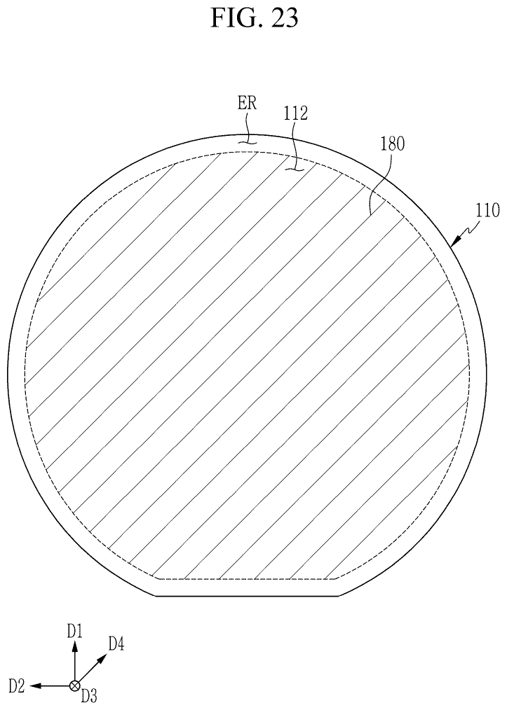

The substrate 110 illustrated in FIG. 23 may be warped along the fourth direction D4 between the first direction D1 and the second direction D2. Accordingly, the grooves 180 formed on the second surface 112 of the substrate 110 may extend along a direction parallel to the fourth direction D4.

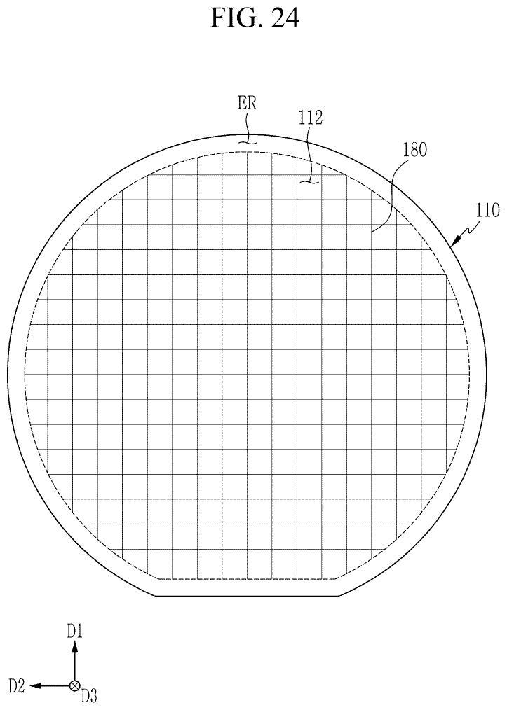

The substrate 110 illustrated in FIG. 24 may be warped along the first direction D1 and the second direction D2. Accordingly, the grooves 180 formed on the second surface 112 of the substrate 110 may include grooves 180 extending along the first direction D1 and grooves 180 extending along the second direction D2.

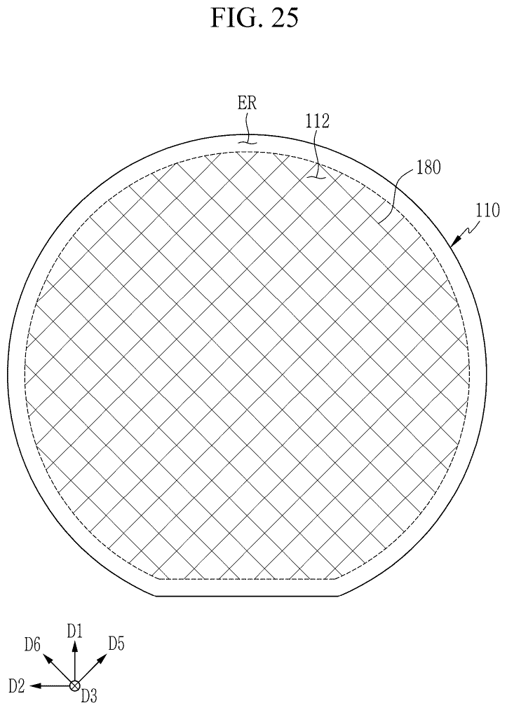

The substrate 110 illustrated in FIG. 25 may be warped along a fifth direction D5 between the first direction D1 and the second direction D2, and along a sixth direction D6 between the first direction D1 and the second direction D2. Accordingly, the grooves 180 formed on the second surface 112 of the substrate 110 may include grooves 180 extending along the fifth direction D5 and grooves 180 extending along the sixth direction D6.

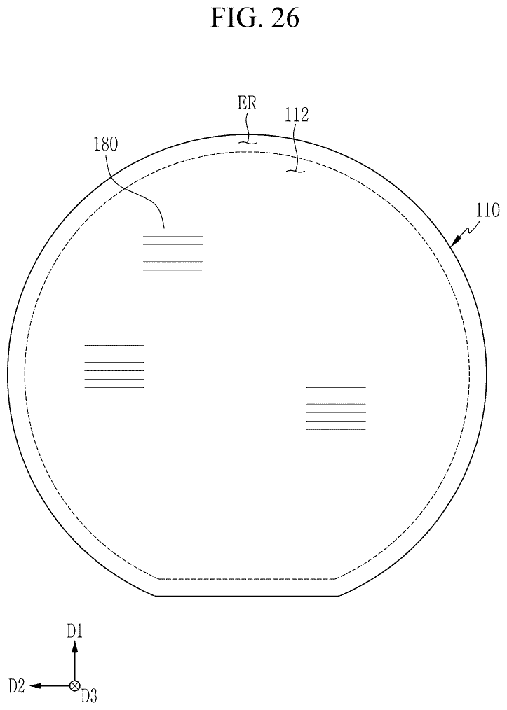

The substrate 110 illustrated in FIG. 26 may be locally warped along the second direction D2 only in some regions. In this case, the grooves 180 may be formed locally only in a region where the warpage is positioned. In an example embodiment, the grooves 180 may be formed along the second direction D2 in a region where the warpage is positioned.

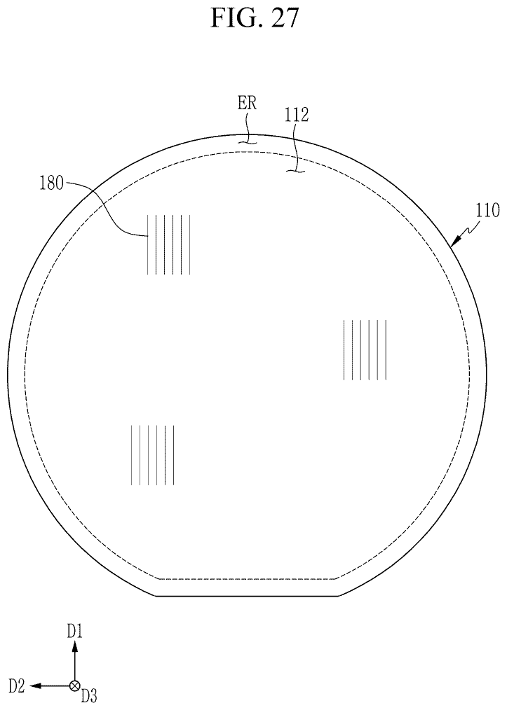

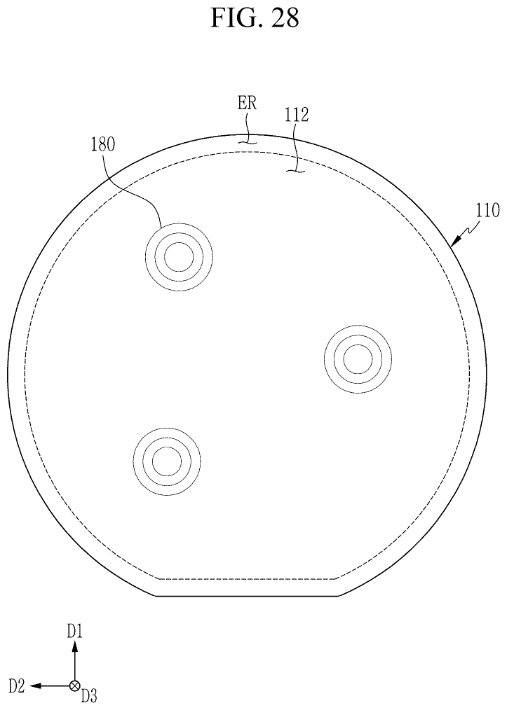

The substrate 110 illustrated in FIG. 27 may be locally warped along the first direction D1 only in some regions. In an example embodiment, the grooves 180 may be formed along the first direction D1 in a region where the warpage is positioned. On the second surface 112 of the substrate 110 illustrated in FIG. 28, the grooves 180 in a circular shape may be formed in a region where the warpage is positioned. Referring to FIG. 28, the centers of the circles formed by each of the plurality of grooves 180 may be positioned at the same point. Referring to FIG. 28, the plurality of grooves 180 may have radii different from adjacent grooves when viewed on a plane.

In an example embodiment, at least one of the grooves having the shape illustrated in FIG. 26 to FIG. 28 may be positioned on the second surface 112 of a substrate 110, respectively. For example, warpages in different directions at different regions of a substrate 110 may occur, and in this case, the grooves 180 may extend in different directions on the second surface 112 of the substrate 110 based on the direction of the warpage formed in each region.

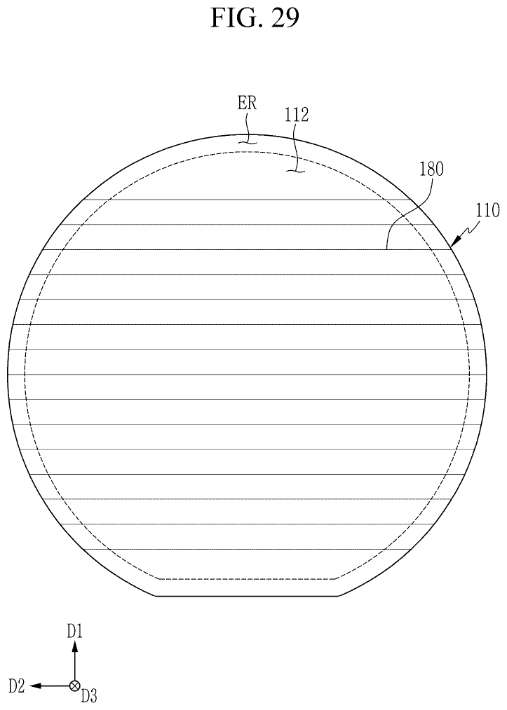

The substrate 110 illustrated in FIG. 29 may be warped along the second direction D2. Accordingly, the grooves 180 formed on the second surface 112 of the substrate 110 may extend along a direction parallel to the second direction D2. Referring to FIG. 29, the grooves 180 according to an example embodiment may extend to the edge region ER of the substrate 110.

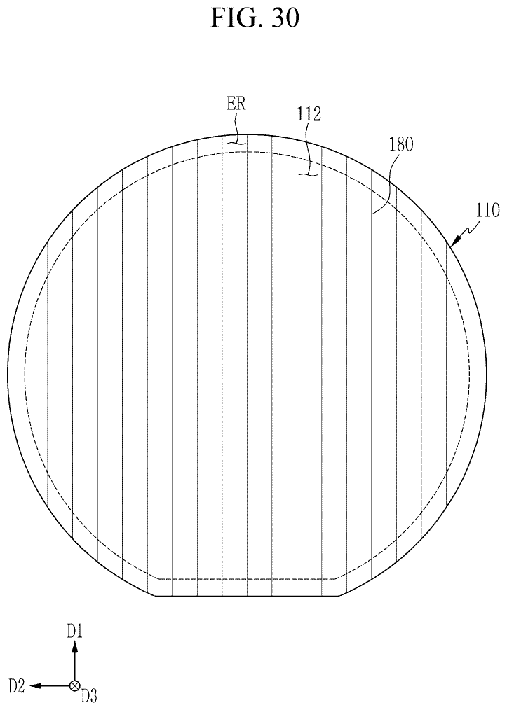

The substrate 110 illustrated in FIG. 30 may be warped along the first direction D1. Accordingly, the grooves 180 formed on the second surface 112 of the substrate 110 may extend along a direction parallel to the first direction D1. Referring to FIG. 30, the grooves 180 according to an example embodiment may extend to the edge region ER of the substrate 110.

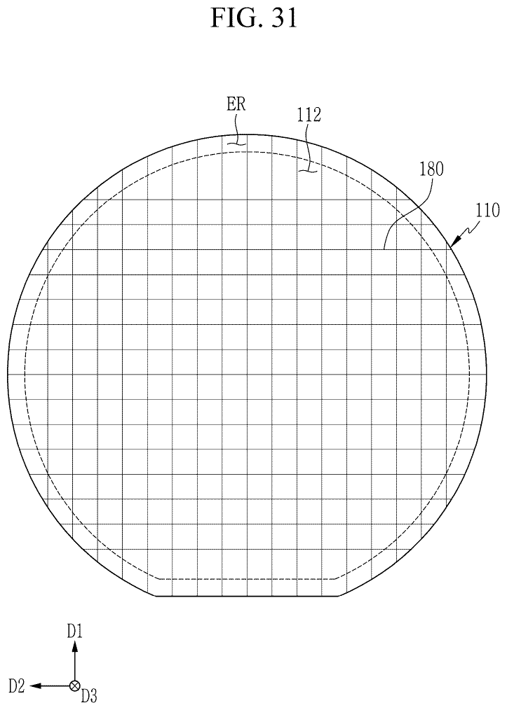

The substrate 110 illustrated in FIG. 31 may be warped along the first direction D1 and the second direction D2. Accordingly, the grooves 180 formed on the second surface 112 of the substrate 110 may include grooves 180 extending along the first direction D1 and grooves 180 extending along the second direction D2. Referring to FIG. 31, the grooves 180 according to an example embodiment may extend to the edge region ER of the substrate 110.

Although aspects of example embodiments have been described in detail above, the scope of the present disclosure is not limited thereto, and various modifications and improvements can be made by those skilled in the art using the basic concept of the present disclosure defined in the following claims, without departing from the scope of the present disclosure.

What is claimed is:

1. A method for manufacturing a semiconductor device, the method comprising:
forming a first conductivity type semiconductor layer on a first surface of a substrate containing SiC;
forming a doping layer by implanting ions into the first conductivity type semiconductor layer;
forming a gate insulation layer on the first conductivity type semiconductor layer;
forming a gate electrode on the gate insulation layer;
forming a source electrode connected to the doping layer;
reducing a thickness of the substrate by performing a thinning process on a second surface opposite to the first surface of the substrate; and
forming a groove in the substrate on the second surface.

2. The method of claim 1, further comprising:
forming a drain electrode on the second surface of the substrate; and
forming a groove in the drain electrode.

3. The method of claim 1, wherein the forming the groove comprises forming, on the second surface, a plurality of first grooves in the substrate that extend in a first direction parallel to the second surface and are spaced apart from each other along a second direction intersecting the first direction.

4. The method of claim 3, wherein the forming the groove further comprises forming, on the second surface, a plurality of second grooves in the substrate that extend in the second direction and are spaced apart from each other along the first direction.

5. The method of claim 1, further comprising measuring warpage of the substrate,
wherein the forming the groove on the second surface is performed based on the warpage.

6. The method of claim 5, wherein the forming the groove further comprises determining whether to form the groove based on a measurement result of the measuring.

7. The method of claim 6, wherein the groove extends in a direction parallel to a direction in which the substrate is warped.

8. The method of claim 6, wherein the groove is locally formed in a portion of which the substrate is warped.

9. The method of claim 1, wherein the forming the groove comprises applying pressure with a tip of a groove-forming device.

10. The method of claim 9, wherein a groove forming device comprises a plurality of tips that have a common height and are spaced apart from each other; and
wherein the forming the groove comprises simultaneously forming a plurality of grooves by applying pressure to the second surface of the substrate with the plurality of tips.

11. The method of claim 10, wherein a pitch of the plurality of tips is greater than or equal to 0.1 mm and less than or equal to 10 mm.

12. The method of claim 10, wherein the groove forming device comprises a material having a hardness higher than SiC.

13. The method of claim 10, wherein the groove forming device contains diamond.

14. A semiconductor device comprising:
a substrate comprising a first surface and a second surface facing each other;
a first conductivity type semiconductor layer provided on the first surface of the substrate;
a doping layer provided in the first conductivity type semiconductor layer;
a gate electrode provided on the first conductivity type semiconductor layer;
a gate insulation layer provided between the first conductivity type semiconductor layer and the gate electrode;
a source electrode connected to the doping layer; and
a drain electrode provided on the second surface of the substrate,
wherein grooves concavely recessed from the second surface toward the first surface are formed in the substrate, and
wherein the drain electrode extends into the grooves.

15. The semiconductor device of claim 14, wherein the drain electrode comprises a third surface facing the second surface of the substrate and a fourth surface facing the third surface of the drain electrode, and
wherein a groove concavely recessed from the fourth surface to the third surface is formed in the drain electrode.

16. The semiconductor device of claim 14, wherein the grooves formed on the second surface of the substrate comprise first grooves that extend in a first direction parallel to the second surface of the substrate.

17. The semiconductor device of claim 16, wherein the grooves formed on the second surface of the substrate further comprise second grooves that extend in a second direction that is parallel to the second surface of the substrate and intersects the first direction.

18. The semiconductor device of claim 14, wherein a pitch of the grooves is greater than or equal to 0.1 mm and less than or equal to 10 mm.

19. A method of manufacturing a semiconductor device, the method comprising:
forming a first conductivity type semiconductor layer on a first surface of a substrate containing SiC;
forming a doping layer by implanting ions into the first conductivity type semiconductor layer;
forming a gate insulation layer on the first conductivity type semiconductor layer;
forming a gate electrode on the gate insulation layer;
forming a first interlayer insulation layer covering the gate electrode;
forming a source electrode connected to the doping layer;
forming a second interlayer insulation layer on the source electrode;
reducing a thickness of the substrate by performing a thinning process on a second surface opposite to the first surface of the substrate;
forming a drain electrode on the second surface of the substrate; and
forming a groove in the substrate on the second surface.

20. The method of claim 19, further comprising forming a groove in the drain electrode.
